(19) United States
(12) Patent Application Publication
(10) Pub. No.: US 2024/0404873 A1
(43) Pub. Date: Dec. 5, 2024

(54) INTEGRATED CIRCUIT CHIP COMPRISING A RADIOFREQUENCY COMPONENT

(71) Applicant: STMicroelectronics International N.V., Geneva (CH)

(72) Inventors: Pascal Chevalier, Chapareillan (FR); Siddhartha Dhar, Delhi (IN); Frederic Monsieur, Pontcharra (FR)

(21) Appl. No.: 18/671,424

(22) Filed: May 22, 2024

(30) Foreign Application Priority Data
May 31, 2023 (FR) 2305465

(51) Int. Cl. H01L 21/762; H01L 21/265; H01L 27/092

(52) U.S. Cl. CPC H01L 21/76283; H01L 21/26506; H01L 27/092

(57) ABSTRACT

The present description concerns an integrated circuit chip including a semiconductor substrate and a radiofrequency component arranged inside and on top of an active region of the semiconductor substrate. The semiconductor substrate includes an amorphous buried layer in contact, by its upper surface, with a lower surface of the active region of the semiconductor substrate.

### CROSS-REFERENCE TO RELATED APPLICATIONS

This application claims priority to French Patent Application No. FR 2305465, filed on May 31, 2023, which application is hereby incorporated herein by reference.

### TECHNICAL FIELD

The present disclosure generally concerns the field of electronic integrated circuit chips. It more particularly aims at the field of electronic integrated circuit chips comprising a radiofrequency component.

### BACKGROUND

One generally calls radiofrequency components intended to receive AC electric signals at frequencies within the range from 3 kHz to 30 GHz. Among known radiofrequency components, one can find active components such as amplifiers, mixers, and data converters, and passive components such as capacitors, inductances, and antennas.

### SUMMARY

There exists a need to improve known radiofrequency components and their manufacturing methods.

An embodiment provides an integrated circuit chip comprising a semiconductor substrate and a radiofrequency component arranged inside and on top of an active region of the semiconductor substrate, the semiconductor substrate comprising an amorphous buried layer in contact, by its upper surface, with a lower surface of the active region of the semiconductor substrate.

According to an embodiment, the active region is flush, by its upper surface, with a first surface of the semiconductor substrate.

According to an embodiment, the integrated circuit chip comprises in contact with the first surface of the semiconductor substrate, an interconnection network.

According to an embodiment, the active region is laterally delimited by insulating structures.

According to an embodiment, the insulating structures are insulating trenches.

According to an embodiment, the insulating structures correspond to an assembly of a plurality of laterally-appended doped regions with an alternation of the conductivity type.

According to an embodiment, the amorphous buried layer is in contact with the insulating structures.

According to an embodiment, the radiofrequency component is a MOS transistor.

Another embodiment provides a method of manufacturing an integrated circuit chip comprising a semiconductor substrate and a radiofrequency component formed inside and on top of an active region of the semiconductor substrate, comprising a step of forming, in the semiconductor substrate, of an amorphous buried layer in contact, by its upper surface, with a lower surface of the active region of the semiconductor substrate.

According to an embodiment, the step of forming of the amorphous buried layer is carried out by ion implantation.

According to an embodiment, the step of forming of the amorphous buried layer is carried out from a first surface of the semiconductor substrate, before the forming of an interconnection network on the first surface of the semiconductor substrate.

According to an embodiment, the step of forming of the amorphous buried layer is carried out after the forming of an interconnection network on a first surface of the semiconductor substrate, the step of forming of the amorphous buried layer being carried out from a second surface of the semiconductor substrate, opposite to the first surface.

According to an embodiment, the method comprises a step of thinning of the semiconductor substrate from its second surface, after the step of forming of the interconnection network and before the step of forming of the amorphous buried layer.

Another embodiment provides an integrated circuit chip comprising a semiconductor substrate and a radiofrequency component arranged inside and on top of an active region of the semiconductor substrate, the semiconductor substrate comprising a layer comprising a plurality of PN junctions in contact, by its upper surface, with a lower surface of the active region of the semiconductor substrate.

According to an embodiment, the layer comprising a plurality of PN junctions is formed of a plurality of laterally-appended regions.

According to an embodiment, the appended regions have alternated conductivity types.

According to an embodiment, the active region is flush, by its upper surface, with a first surface of the semiconductor substrate.

According to an embodiment, the integrated circuit chip comprises, in contact with the first surface of the semiconductor substrate, an interconnection network.

According to an embodiment, the active region is laterally delimited by insulating structures.

According to an embodiment, the insulating structures are insulating trenches.

According to an embodiment, the layer comprising a plurality of PN junctions is in contact with the insulating structures.

According to an embodiment, the radiofrequency component is a MOS transistor.

Another embodiment provides a method of manufacturing an integrated circuit chip comprising a semiconductor substrate and a radiofrequency component formed inside and on top of an active region du semiconductor substrate, comprising a step of forming, in the semiconductor substrate, of a layer comprising a plurality of PN junctions in contact, by its upper surface, with a lower surface of the active region of the semiconductor substrate.

According to an embodiment, the step of forming of the layer comprising a plurality of PN junctions is carried out by ion implantation.

According to an embodiment, the step of forming of the layer comprising a plurality of PN junctions is carried out after the forming of an interconnection network on a first surface of the semiconductor substrate, the step of forming of the layer comprising a plurality of PN junctions in contact being carried out from a second surface of the semiconductor substrate, opposite to the first surface.

According to an embodiment, the method comprises a step of thinning of the semiconductor substrate from its second surface, after the step of forming of the interconnection network and before the step of forming of the layer comprising a plurality of PN junctions.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a partial and simplified cross-section view of an electronic chip comprising a radiofrequency component according to a first embodiment;

FIG. 2 is a partial and simplified cross-section view of an electronic chip comprising a radiofrequency component according to a second embodiment;

FIG. 3A, FIG. 3B, and FIG. 3C illustrate successive steps of a method of manufacturing the electronic chip of FIG. 1;

FIG. 4A, FIG. 4B, FIG. 4C, and FIG. 4D illustrate successive steps of another method of manufacturing the electronic chip of FIG. 1; and

FIG. 5 is a partial and simplified cross-section view of an electronic chip comprising a radiofrequency component according to a third embodiment.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

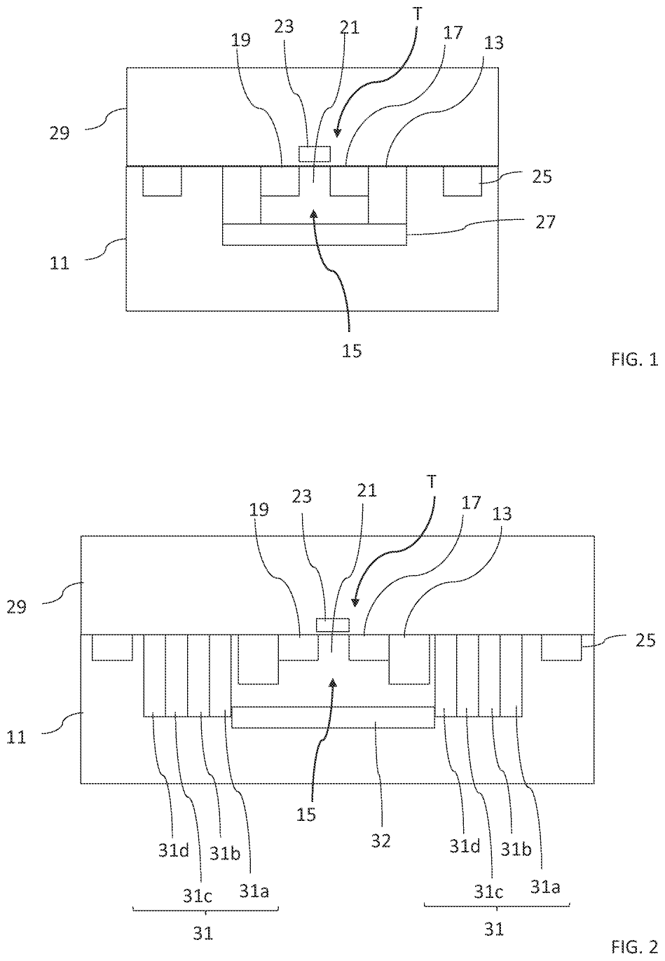

FIG. 1 is a partial and simplified cross-section view of an electronic chip comprising a radiofrequency component according to a first embodiment.

The electronic chip illustrated in FIG. 1 comprises a doped semiconductor substrate 11 of a first conductivity type, for example of type P. Substrate 11 is for example a single-crystal substrate, for example made of silicon.

The electronic chip illustrated in FIG. 1 further comprises a radiofrequency component formed inside and on top of an active region 15 of semiconductor substrate 11. As an example, active region 15 is flush with the upper surface of semiconductor substrate 11. Active region 15 is, for example, the active region of the radiofrequency component, here a transistor T. Transistor T is for example a MOS (“Metal Oxide Semiconductor”) transistor. As an example, transistor T is a complementary metal oxide semiconductor (CMOS) transistor. As a variant, transistor T is a bipolar CMOS (BiCMOS) transistor. The electronic chip is for example a radiofrequency switch, for example used in radio communication applications, for example of WIFI type or according to any other radio communication standard, for example narrow-band communications in the field of the Internet of things (IoT). As non-limiting examples, the electronic chip may be formed in high-resistivity CMOS (“Complementary Metal Oxide Semiconductor”) technology or in bipolar CMOS technology.

In the present disclosure, one considers as being the front surface of semiconductor substrate 11, the upper surface of substrate 11 in the orientation of FIG. 1, that is, the surface of substrate 11 having active region 15 flush therewith and as being the rear surface of semiconductor substrate 11, the lower surface of substrate 11 in the orientation of FIG. 1.

As an example, active region 15 is laterally delimited by insulating trenches 13 formed in semiconductor substrate 11. Insulating trenches 13 are, for example, shallow trenches, for example of the type generally designated by initials STI (“Shallow Trench Isolation”). As an example, the depth of insulating trenches 13 extends down to a depth in the range from 300 nm and 500 nm. As an example, insulating trenches 13 extend in substrate 11 from the front surface of substrate 11. Insulating trenches 13 are for example flush with the front surface of substrate 11. Insulating trenches 13 are, for example, filled with a dielectric material, for example with oxide, for example silicon dioxide.

As an example, semiconductor substrate 11 comprises, in active region 15, a drain region 17 of transistor T, a source region 19 of transistor T, and a channel-forming region 21 of transistor T formed between drain region 17 and source region 19. As an example, drain region 17 and source region 19 are flush with the front surface of semiconductor substrate 11. As an example, drain region 17 and source region 19 are doped with a second conductivity type, opposite to the first conductivity type, for example type N.

As an example, channel-forming region 21 is topped with a gate 23 of transistor T. The gate 23 of transistor T is for example separated from active layer 15 by a gate insulator. The gate insulator is for example based on oxide, for example on silicon oxide. The gate 23 of transistor T is for example made of polysilicon.

Transistor T further comprises body contacting regions 25, for example formed in substrate 11 outside of active region 15. As an example, the transistor comprises two body contacting regions 25 located on either side of active region 15. As an example, body contacting regions 25 are flush with the front surface of semiconductor substrate 11. Body contacting regions 25 are, for example, doped with the first conductivity type, for example type P.

Active region 15 is, further, delimited in depth by an amorphous buried layer 27, amorphous buried layer 27 being in contact, by its upper surface, with the lower surface of active region 15.

Amorphous buried layer 27 extends, for example, parallel to the front surface of semiconductor substrate 11. As an example, amorphous buried layer 27 locally extends in front of active region 15. As an example, amorphous buried layer 27 extends under insulating trenches 13. In the example of FIG. 1, amorphous buried layer 27 is, preferably, in contact by its upper surface with the lower surface of insulating trenches 13. Amorphous layer 27 has, for example, a thickness in the range from 100 nm to 500 nm, for example in the range from 150 nm to 300 nm, for example in the order of 200 nm.

Transistor T is for example topped with an interconnection network 29 comprising elements of connection to the source 19, to the drain 17, and to the gate 23 of transistor T. As an example, interconnection network 29 covers the front surface of semiconductor substrate 11 and of gate 23. Interconnection network 29 is for example in contact with the front surface of substrate 11. As an example, gate 23 is separated from interconnection network 29 by an insulating layer, not shown. Interconnection network 29 for example comprises a stack of conductive levels, for example metallic, and of insulating layers having conductive vias, for example metallic, interconnecting conductive tracks of different conductive levels, formed therein.

An advantage of the present embodiment is that the amorphous buried layer enables to locally increase the impedance of semiconductor substrate 11, blocking possible parasitic currents likely to be generated between active region 15 and the rest of substrate 11, for example between active region 15 and body contacting regions 25, under the effect of the radiofrequency signals transiting through the component.

Another advantage of the present embodiment is to enable to do away with a substrate of SOI (“Silicon On Insulator”) type comprising a trap-rich layer at the interface between a buried oxide (BOX) layer and a support substrate, currently used to decrease the above-mentioned parasitic currents.

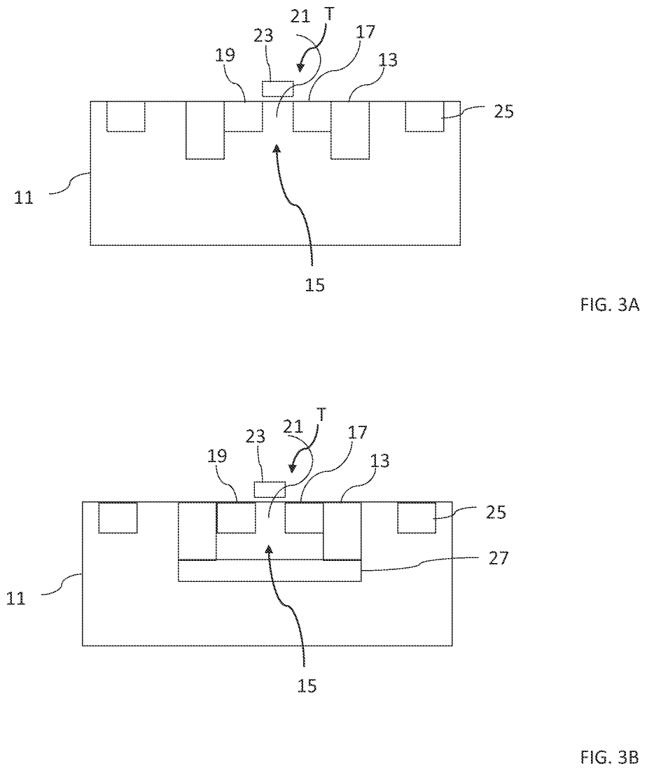

FIG. 2 is a partial and simplified cross-section view of an electronic chip comprising radiofrequency components according to a second embodiment.

The electronic chip illustrated in FIG. 1 is similar to the electronic chip illustrated in FIG. 2, with the difference that the electronic chip illustrated in FIG. 2 comprises, on either side of active region 15 and of insulating trenches 23, insulating structures 31 formed of PN junctions.

In FIG. 2, the electronic chip thus comprises, on each side of active layer 15, between insulating trench 13 and body area 25, an insulating structure 31. The chip illustrated in FIG. 2 comprises, for example, two insulating structures 31.

As an example, insulating structures 31 correspond to an assembly of a plurality of appended doped regions with an alternation of the conductivity type. In FIG. 2, insulating structures 31 comprise four regions 31a, 31b, 31c, and 31d. As an example, region 31a is in contact by a lateral surface with region 31b, region 31b is in contact by two opposite surfaces with regions 31a and 31c, region 31c is in contact by two opposite lateral surfaces with region 31d, and region 31d is in contact by a lateral surface with region 31c.

As an example, regions 31a, 31b, 31c, and 31d are arranged so that region 31a is located close to insulating trench 13. As an example, region 31a and region 31c are doped with the second conductivity type, that is, type N. As an example, region 31b and region 31d are doped with the first conductivity type, that is, type P.

As an example, regions 31a, 31b, 31c, and 31d extend in semiconductor substrate 11 down to a depth greater than the depth of insulating trenches 13. As an example, regions 31a, 31b, 31c, and 31d extend in semiconductor substrate 11 down to a depth in the range from 500 nm to 1 μm. Regions 31a, 31b, 31c, and 31d are for example flush with the front surface of semiconductor substrate 11, by their upper surfaces. As an example, regions 31a, 31b, 31c, and 31d are aligned by their lower surfaces, that is, they all have the same depth.

As an example, the electronic chip illustrated in FIG. 2 comprises an amorphous buried layer 32, similar to the amorphous buried layer 27 illustrated in FIG. 1, which is for example formed more deeply than layer 27 is in the embodiment illustrated in FIG. 1. In this embodiment, layer 32 is for example formed so that at least a portion of each of its two opposite sides located in front of the insulating structures is in contact with the sides of the insulating structures and more precisely with the sides of the two regions 31a.

An advantage of the second embodiment is that the insulating structures provide a high resistance created by the PN junctions, thus decreasing horizontal parasitic currents extending from active region 15 into substrate 11.

Another advantage of the present embodiment is that it enables to create the amorphous buried layer at a greater depth under the radiofrequency component, thus limiting risks linked to the damaging of the component during the implantation.

Still another advantage of the present embodiment is that it enables to control the depth of the amorphous buried layer and that of insulating trenches 13 in independent fashion.

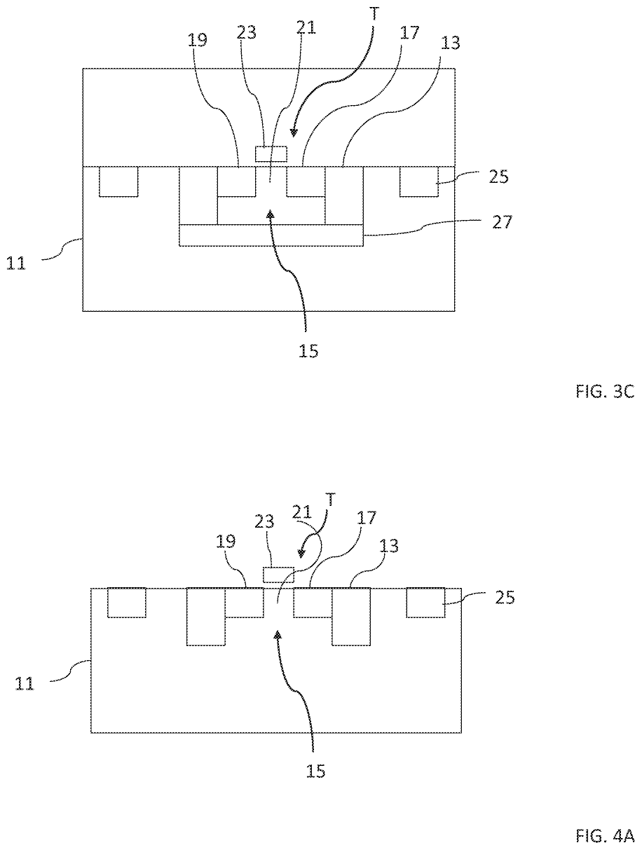

FIG. 3A, FIG. 3B, and FIG. 3C illustrate successive steps of a method of manufacturing the electronic chip according to the first embodiment illustrated in FIG. 1.

FIG. 3A more precisely illustrates an initial structure comprising semiconductor substrate 11 having the source 19, drain 17, gate 23, and body 25 regions of transistor T and insulating trenches 13 formed therein.

FIG. 3B illustrates a structure obtained at the end of a step of forming of amorphous buried layer 27 in the initial structure illustrated in FIG. 3A.

During this step, layer 27 is formed by amorphization of a portion of semiconductor substrate 11.

During this step, the amorphization is carried out by ion implantation on the front surface side of semiconductor substrate 11. In other words, during this step, the amorphization is performed by an implantation on the side of the active region 15 of semiconductor substrate 11.

As an example, layer 27 is formed by implantation of boron and oxygen ions.

As an example, in order to amorphize substrate 11 to form layer 27, the ions have an acceleration having an energy in the range from 150 KeV to 300 KeV, for example in the order of 250 KeV. As an example, the ions have an activation time in the range from 0.5 to 3 seconds, for example in the order of 1 second. The ions have, for example, an activation temperature in the range from 400° C. to 80° C., for example in the range from 500° C. to 700° C., for example in the order of 600° C.

As an example, to form the amorphous buried layer located under active region 15, the amorphization is performed through a mask.

Drain 17, source 19, and gate 23 are transparent for the implantation of dopants, that is, they do not play the role of a mask, which allows the amorphization of layer 27 with no impact of drain 17, of source 19, and of gate 23.

At the end of this step, an anneal step enabling to correct the defects created at the surface by the implantation and to reactivate the surface dopants may be provided. As an example, this anneal step is for example locally performed by laser.

FIG. 3C illustrates a structure obtained at the end of a step of forming of interconnection network 29 on the upper surface of the structure illustrated in FIG. 3B.

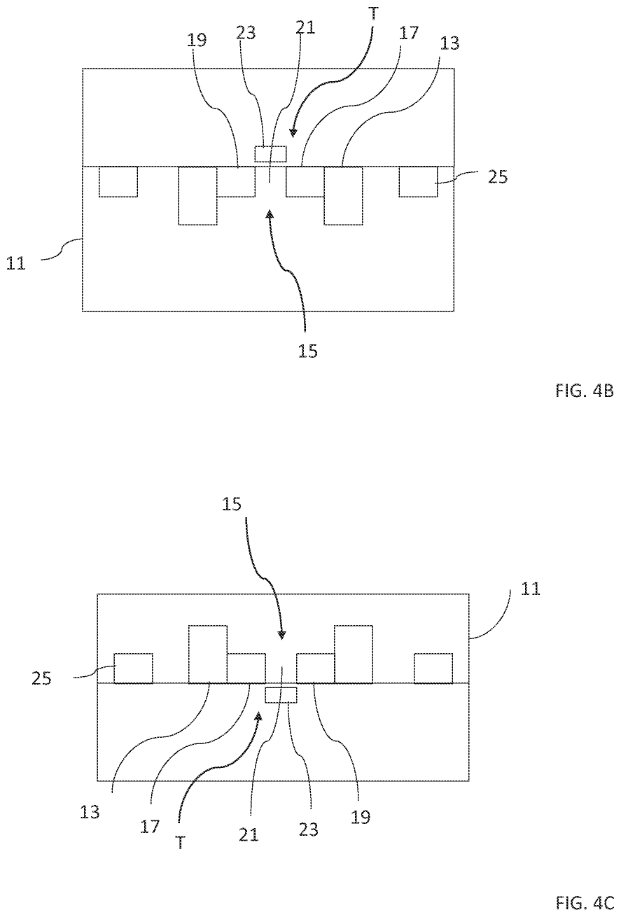

FIG. 4A, FIG. 4B, FIG. 4C, and FIG. 4D illustrate another method of manufacturing the electronic chip according to the first embodiment illustrated in FIG. 1.

More precisely, the steps of the method illustrated in FIGS. 4A to 4D are similar to those of the method illustrated in FIG. 3A to 3C, with the difference that in the method illustrated in FIGS. 4A to 4D, the step of forming of an amorphous buried layer 27′ is carried out after the forming of interconnection network 29 and that amorphous buried layer 27′ is formed from the rear surface of substrate 11.

FIG. 4A illustrates an initial structure identical to the initial structure illustrated in FIG. 3A.

FIG. 4B illustrates a structure obtained at the end of a step of forming of interconnection network 29 on the upper surface of the structure illustrated in FIG. 4A and more particularly on top of and in contact with the front surface of substrate 11.

FIG. 4C illustrates a structure obtained at the end of a step of thinning of the semiconductor substrate 11 of the structure illustrated in FIG. 4B. More particularly, during this step, the structure illustrated in FIG. 4B is flipped to be able to remove a portion of semiconductor substrate 11 from its rear surface. The removal of a portion of a semiconductor substrate 11 from its rear surface is, for example performed by grinding and/or by chemical mechanical polishing (CMP). As an example, semiconductor substrate 11 is thinned to reach a thickness in the range from 3 μm to 30 μm, for example in the range from 3 μm to 10 μm, for example in the order of 5 μm.

It should be noted that FIGS. 4C and 4D are turned upside down with respect to the orientation of FIGS. 4A and 4B.

FIG. 4D illustrates a structure obtained at the end of a step of forming of the amorphous buried layer in the initial structure illustrated in FIG. 4C.

The step illustrated in FIG. 4D is, for example, similar to that illustrated in FIG. 3B, with the difference that during the step illustrated in FIG. 4D, the forming of amorphous buried layer 27′ is performed by ion implantation on the rear surface side of semiconductor substrate 11 and after the step of forming of interconnection network 29. As an example, amorphous layer 27′ may extend under the active layer beyond the location facing active layer 15, for example over the entire surface of substrate 11.

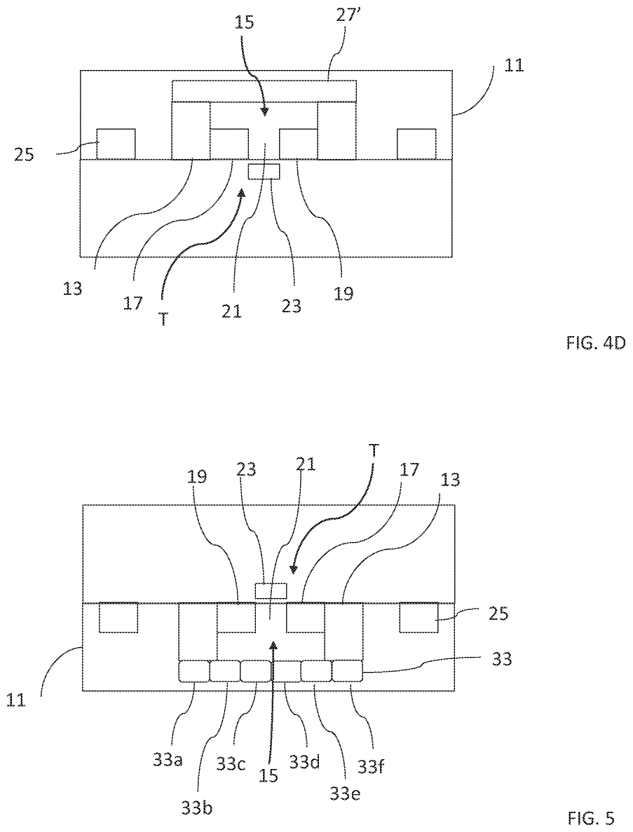

FIG. 5 is a partial and simplified cross-section view of an electronic chip comprising a radiofrequency component according to a third embodiment.

More particularly, the electronic chip illustrated in FIG. 5 is similar to that illustrated in FIG. 1, with the difference that it comprises, instead of amorphous buried layer 27, a layer 33 comprising a plurality of PN junctions.

Layer 33 thus comprises a plurality of laterally-appended regions 33a, 33b, 33c, 33d, 33e, and 33f. As an example, region 33a is for example in contact by a side with a side of region 33b, region 33b is in contact with two opposite sides with the sides of regions 33a and 33c, region 33c is in contact by two opposite sides with the sides of regions 33b and 33d, region 33d is in contact by two opposite sides with the sides of regions 33c and 33e, region 33e is in contact by two opposite sides with the sides of regions 33d and 33f, and region 33f is in contact by a side with the side of region 33e. As an example, regions 33a, 33b, 33c, 33d, 33e, and 33f are doped with an alternation of conductivity type. Regions 33a, 33c, and 33e are, for example, doped with the first conductivity type, for example type P. Regions 33b, 33d, and 33f are, for example, doped with the second conductivity type, for example type N.

As an example, layer 33 is formed by local implantation of N-type dopant elements and of P-type dopant elements. The dopant implantation may be performed from the rear surface of semiconductor substrate 11, for example in the method described in FIG. 4A to 4D to replace the amorphization step illustrated in FIG. 4D.

An advantage of the embodiment illustrated in FIG. 5 is that it enables to increase the impedance in depth between the two insulating trenches 13, thus limiting parasitic currents originating from active region 15 towards the rest of substrate 11.

Various embodiments and variants have been described. Those skilled in the art will understand that certain features of these various embodiments and variants may be combined, and other variants will occur to those skilled in the art. In particular, although in the embodiments, layer 27 has been shown locally under active region 15, it may in practice be formed throughout the entire wafer, that is, extend over the entire surface of semiconductor substrate 11. Further, although there has been shown in the different embodiments a single radiofrequency component per active region 15, in practice, a plurality of components may be formed within a same active region, the amorphous buried layer thus being formed in front of radiofrequency components.

Further, the methods illustrated in FIGS. 3 and 4 may easily be adapted to the manufacturing of the electronic chip illustrated in FIG. 2.

Moreover, in the embodiment illustrated in FIG. 2, it may be provided to omit insulating trenches 13.

Eventually, in the embodiments of FIGS. 2 and 5, although insulating structures 31 and layer 33 respectively comprise 4 and 6 doped regions, in practice, they may comprise a different number of regions, for example a higher number of regions.

Finally, the practical implementation of the described embodiments and variants is within the abilities of those skilled in the art based on the functional indications given hereabove.

What is claimed is:

1. An integrated circuit chip comprising:
a semiconductor substrate; and
a radiofrequency component arranged inside and on top of an active region of the semiconductor substrate, the semiconductor substrate comprising an amorphous buried layer in contact, by its upper surface, with a lower surface of the active region of the semiconductor substrate.

2. The chip according to claim 1, wherein the radiofrequency component is a component intended to receive AC electric signals at frequencies within the range from 3 kHz to 30 GHz.

3. The chip according to claim 1, wherein the active region is flush, by its upper surface, with a first surface of the semiconductor substrate.

4. The chip according to claim 3, further comprising an interconnection network in contact with the first surface of the semiconductor substrate.

5. The chip according to claim 1, wherein the active region is laterally delimited by insulating structures.

6. The chip according to claim 5, wherein the insulating structures are insulating trenches.

7. The chip according to claim 5, wherein the insulating structures correspond to an assembly of a plurality of laterally-appended doped regions laterally with alternating doping types.

8. The chip according to claim 5, wherein the amorphous buried layer is in contact with the insulating structures.

9. The chip according to claim 1, wherein the radiofrequency component is a MOS transistor.

10. A method of manufacturing an integrated circuit chip, the method comprising:
forming a radiofrequency component inside and on top of an active region of a semiconductor substrate; and
forming, in the semiconductor substrate, an amorphous buried layer in contact, by its upper surface, with a lower surface of the active region of the semiconductor substrate.

11. The method according to claim 10, wherein the forming of the amorphous buried layer is carried out by ion implantation.

12. The method according to claim 11, wherein the forming of the amorphous buried layer is carried out from a first surface of the semiconductor substrate, before the forming of an interconnection network on the first surface of the semiconductor substrate.

13. The method according to claim 11, wherein the forming of the amorphous buried layer is carried out after the forming of an interconnection network on a first surface of the semiconductor substrate, the forming of the amorphous buried layer being carried out from a second surface of the semiconductor substrate, opposite to the first surface.

14. The method according to claim 13, further comprising thinning of the semiconductor substrate from its second surface, after the forming of the interconnection network and before the step of forming of the amorphous buried layer.

15. A method of manufacturing an integrated circuit chip, the method comprising:
forming a radiofrequency (RF) component at a first side of a semiconductor substrate, the semiconductor substrate comprising the first side and an opposite second side, the RF component comprising a device region and a trench isolation region laterally surrounding the device region;
thinning the semiconductor substrate from the second side to form a thinned substrate; and
locally forming a buried isolation layer by ion implantation, the buried isolation layer aligned with the trench isolation region.

16. The method of claim 15, wherein forming the trench isolation region comprises forming a shallow trench isolation comprising a dielectric material.

17. The method of claim 15, wherein forming the trench isolation region comprises forming a plurality of doped regions having opposite doping types.

18. The method of claim 15, further comprising forming an interconnection network before the thinning.

19. The method of claim 15, further comprising forming insulating structures disposed around the trench isolation region, the insulating structures extending deeper into the substrate than the trench isolation region.

20. The method of claim 19, the insulating structures corresponding to an assembly of a plurality of laterally-appended doped regions laterally with alternating doping type.

21. The method of claim 19, wherein the buried isolation layer is in contact with the insulating structures.
